(19) United States
(12) Patent Application Publication
(10) Pub. No.: US 2026/0299011 A1
(43) Pub. Date: Oct. 1, 2026

(54) ELECTRONIC SYSTEM FOR TESTING AN EMBEDDED APPLICATION, AND COMMUNICATION METHOD

(71) Applicant: STMicroelectronics International N.V., Geneva (CH)

(72) Inventor: Alexis Masson, Le Mans (FR)

(21) Appl. No.: 19/559,083

(22) Filed: Mar. 6, 2026

(30) Foreign Application Priority Data
Mar. 25, 2025 (FR) FR2503062

(51) Int. Cl. G01R 31/28

(52) U.S. Cl. CPC G01R 31/2844; G01R 31/2837

(57) ABSTRACT

An example electronic system for testing an embedded application includes a device under test, an auxiliary device, and a test computer. The device under test includes a first microcontroller having first pins. The auxiliary device is separate from and electrically connected to the device under test. The auxiliary device includes a second microcontroller having second pins electrically connected to the first pins. The test computer consults a database to identify second pins electrically connected to a target first pin associated with a request to be executed. The test computer transmits interrogation requests to the auxiliary device for each identified second pin to determine a current state of the second microcontroller. The test computer receives responses indicating the current state for each identified second pin. The test computer selects one of the identified second pins based on the responses received. The test computer transmits the request to the auxiliary device specifying the selected second pin for execution.

### CROSS-REFERENCE TO RELATED APPLICATIONS

This application claims the benefit of French Application FR2503062, filed on Mar. 25, 2025, which application is hereby incorporated herein by reference.

### TECHNICAL FIELD

This description relates in general to the field of testing applications embedded in electronic devices.

### BACKGROUND

Programmable electronic devices are becoming increasingly complex and often more generic. They are used in many contexts and are subject to regular updates, in particular software updates.

These electronic devices are generally provided with one or more communication bus(es) for receiving and/or transmitting data, for example for obtaining data from sensors and/or controlling actuators.

This results in a need for tests to verify that the behavior of applications embedded in these electronic devices under test (DUT) complies with expectations.

In order to test an application embedded in an electronic device, the application is loaded into this electronic device and then executed, and a test computer may be present to analyze the behavior of the electronic device under test, in particular at the level of the data exchanges on the communication bus(es).

However, there is a need to have a test electronic system, making it possible to test the application embedded on the electronic device under test, but also to be able to obtain at least one data associated with the electronic device under test while minimizing the risks of disturbing the tests in progress.

### SUMMARY

An embodiment electronic system is provided that includes a first electronic device, a second electronic device, and a test computer. The first electronic device includes a first microcontroller that has first pins, and at least one first electrical connector having first ports, where each first port is electrically connected to at least one of the first pins. The second electronic device is separate from the first electronic device and is configured to communicate with at least the first electronic device and to receive and execute requests from the test computer. The second electronic device includes a second microcontroller having second pins, and at least one second electrical connector having second ports, where each second port is electrically connected to at least one of the second pins, and the second electrical connector is electrically connected to the first electrical connector to communicate with the first electronic device. The test computer is configured to communicate with at least the second electronic device and to consult at least one database to determine which of the second pins are electrically connected to each of the first pins. The test computer includes a processor and a memory storing a program and coupled to the processor, where the processor is configured to execute the program that includes instructions which when executed enable the processor to identify, from the at least one database, all the second pins electrically connected to a first identified pin associated with a main request to be transmitted, transmit to the second electronic device a request to interrogate a current state of the second microcontroller for each of the second pins electrically connected to the first identified pin to execute the main request using that second pin, receive from the second electronic device a response for each of the second pins electrically connected to the first identified pin where each response indicates the current state of the second microcontroller, select a second selected pin from the second pins identified according to the responses received, and transmit to the second electronic device the main request that specifies the second selected pin, where the second selected pin is electrically connected to the first identified pin.

An embodiment method for communicating between a first electronic device, a second electronic device, and a test computer is provided. The first electronic device includes a first microcontroller having first pins. The first electronic device also includes at least one first electrical connector having first ports. Each first port is electrically connected to at least one of the first pins. The second electronic device is separate from the first electronic device. The second electronic device is configured to communicate with at least the first electronic device. The second electronic device is configured to receive and execute requests from the test computer. The second electronic device includes a second microcontroller having second pins. The second electronic device also includes at least one second electrical connector having second ports. Each second port is electrically connected to at least one of the second pins. The second electrical connector is electrically connected to the first electrical connector to communicate with the first electronic device. The test computer is configured to communicate with at least the second electronic device. The test computer is configured to consult at least one database to determine which of the second pins are electrically connected to each of the first pins. The method includes identifying the second pins electrically connected to a first identified pin. The first identified pin is associated with a main request to be transmitted. The identification is performed from the at least one database. The method includes transmitting to the second electronic device a request to interrogate a current state of the second microcontroller. One interrogation request is transmitted for each of the second pins electrically connected to the first identified pin. Each interrogation request relates to executing the main request using that second pin. The method includes receiving from the second electronic device a response for each of the second pins electrically connected to the first identified pin. Each response indicates the current state of the second microcontroller. The method includes selecting a second selected pin from the second pins electrically connected to the first identified pin. The selection is made according to the responses received. The method includes transmitting to the second electronic device the main request. The main request specifies the second selected pin. The second selected pin is electrically connected to the first identified pin.

An embodiment electronic system for testing an embedded application is provided. The system comprises a device under test, an auxiliary device, and a test computer. The device under test comprises a first microcontroller. The first microcontroller has first pins. The auxiliary device is separate from the device under test. The auxiliary device is electrically connected to the device under test. The auxiliary device comprises a second microcontroller. The second microcontroller has second pins. One or more of the second pins are electrically connected to one or more of the first pins. The test computer is configured to perform several operations. The test computer consults at least one database. The database is used to identify second pins that are electrically connected to a target first pin. The target first pin is associated with a request to be executed. The test computer transmits interrogation requests to the auxiliary device. The test computer sends one interrogation request for each of the identified second pins. Each interrogation request determines a current state of the second microcontroller. The current state indicates whether the second microcontroller can execute the request using that second pin. The test computer receives responses from the auxiliary device. Each response indicates the current state for one of the identified second pins. The test computer selects one of the identified second pins. The selection is based on the responses received. The test computer transmits the request to the auxiliary device. The request specifies the selected second pin for execution.

### BRIEF DESCRIPTION OF THE DRAWINGS

Other advantages and features of the invention will become apparent upon examining the detailed description of non-limiting embodiments and implementations, and from the appended drawings wherein:

FIG. 1 schematically illustrates an electronic system according to an embodiment, including an electronic device under test, an auxiliary electronic device, and a test computer;

FIG. 2 illustrates an example of a mapping table of pins of a microcontroller with an electrical connector of an electronic device of an electronic system according to one embodiment; and

FIG. 3 illustrates a flow diagram of a method of communication between an electronic device under test, an auxiliary electronic device, and a test computer, of an electronic system according to one embodiment.

### DETAILED DESCRIPTION OF ILLUSTRATIVE EMBODIMENTS

One aspect of the present disclosure relates to an electronic system, remedying all or some of the disadvantages mentioned above.

The electronic system comprises a first electronic device, so-called under test, adapted to test an embedded application, a second electronic device, so-called auxiliary, and a test computer.

The first electronic device includes: a first microcontroller, comprising first pins; and at least one first electrical connector, comprising first ports, each first port being electrically connected to at least one first pin.

The second electronic device is distinct from the first electronic device, and is configured to communicate with at least the first electronic device and to receive and execute requests from a test computer. It includes: a second microcontroller, comprising second pins; and at least one second electrical connector, comprising second ports, each port being electrically connected to at least one second pin, the second electrical connector being electrically connected to the first electrical connector to communicate with the first electronic device.

The test computer is configured to communicate with at least the second electronic device and to consult at least one database making it possible to know the second pins electrically connected to each first pin. It includes a processing unit configured to: identify, from said database, all the second pins electrically connected to a first pin, referred to as identified, associated with a main request to be transmitted; transmit to the second electronic device, for each second pin identified, a request to interrogate the current state of the microcontroller to execute the main request using said second pin identified; receive from the second electronic device a response on the current state of the microcontroller for each of the second pins identified; select a second pin from the second pins identified, according to the replies received; transmit to the second electronic device said main request which mentions the second pin selected, the latter being electrically connected to the first pin identified.

The electronic system is configured to provide communication between the electronic device under test, the auxiliary electronic device, and the test computer that consults the database(s). Thus the test computer can transmit to the auxiliary electronic device a main request to be executed, this main request being associated with an identified pin of the microcontroller of the electronic device under test. Thus the test computer does not interact directly with the device under test.

The electronic system takes into account information contained in at least one database that makes it possible to know which are the second pins of the microcontroller of the auxiliary electronic device that are electrically connected to each first pin of the microcontroller of the electronic device under test.

According to one embodiment, the database(s) comprise(s) at least the pin mapping table of the microcontroller of the electronic device under test, at least the pin mapping table of the microcontroller of the auxiliary electronic device, and at least the table of electrical interconnection between the electronic device under test and the auxiliary electronic device. It also takes into account the current state of the auxiliary electronic device on its ability to execute the main request using either of the pins of its microcontroller.

According to one embodiment, the identification step is implemented by the test computer using: at least one mapping table for the electrical connections between the first pins and the first ports of the first electronic device; at least one table of electrical interconnection between the first ports and the second ports; and at least one mapping table of the electrical connections between the second pins and the second ports of the second electrical device. These tables may be stored in said at least one database consultable by the test computer.

According to one embodiment, the processing unit is configured to identify a first pin, then called the first identified pin, associated with the main request to be transmitted.

According to one embodiment, the processing unit is configured to: assign a selection value to each second pin identified according to its response; when selecting, select the second pin that has the highest value.

According to one embodiment, upon selection, the second selected pin has the highest value and higher than a selection threshold.

According to one embodiment, the processing unit is configured to assign: a value V1 when the second identified and interrogated pin is available and it supports a functionality required by the main request in a hardware manner; a value V2, lower than V1, when the second pin identified and interrogated is available and it supports a functionality required by the main request in an emulated manner; a value V3, lower than V2, when the second pin identified and interrogated supports said required functionality but is not available; a value V4, lower than V3, when the second pin identified and interrogated does not support said required functionality.

According to one embodiment, said at least one database includes pin mapping tables of various first electronic devices. The processing unit may be configured to identify the first electronic device connected to the second electronic device, and to identify, in the first database, the associated pin mapping table.

According to one embodiment, the first microcontroller includes a memory in which an embedded application to be tested is stored.

According to one embodiment, said at least one database is stored in a non-volatile memory of the test computer or of a remote server.

According to another aspect, a method for communicating between a first electronic device, a second electronic device and a test computer of an electronic system according to any one of the preceding features is proposed, including the following steps: identifying, by the processing unit, from said at least one database, all of the second pins electrically connected to a first pin, so-called identified, associated with a main request to be transmitted; transmitting, by the processing unit, to the second electronic device and for each second identified pin, a request to interrogate the current state of the microcontroller to execute the main request using said second identified pin; receiving, by the processing unit, from the second electronic device, a response on the current state of the microcontroller for each of the second identified pins; selecting, by the processing unit, a second pin from the second pins identified, according to the replies received; transmitting, by the processing unit, to the second electronic device said main request which mentions the second pin selected, the latter being electrically connected to the first pin identified.

According to one embodiment, the method may comprise, performed before the step of identifying the second pins electrically connected to the first identified pin, the following step: identifying, by the processing unit, the first pin associated with the main request to be transmitted.

According to one embodiment, the method may include the following steps: assigning, by the processing unit, a selection value to each second pin identified according to its response; during the selection step, selecting, by the processing unit, the second pin that has the highest value.

According to one embodiment, the first electronic device includes an embedded application; and wherein, during the steps ranging from transmitting the interrogation requests to transmitting the main request, the first electronic device tests the embedded application.

According to one embodiment, the method may include, performed following the step of transmitting the main request, a step of executing the main request by the second electronic device using the second pin selected.

In the figures and in the following description, the same references represent identical or similar elements. In addition, the different elements are not plotted to scale so as to favour clarity of the figures. Moreover, the different embodiments and variants are not exclusive of each other and may be combined together.

Unless indicated otherwise, the terms “substantially”, “about”, “in the range of” mean within a 10% margin, and preferably within a 5% margin. Moreover, the terms “between . . . and . . . ” and the like mean that the bounds are included, unless stated otherwise.

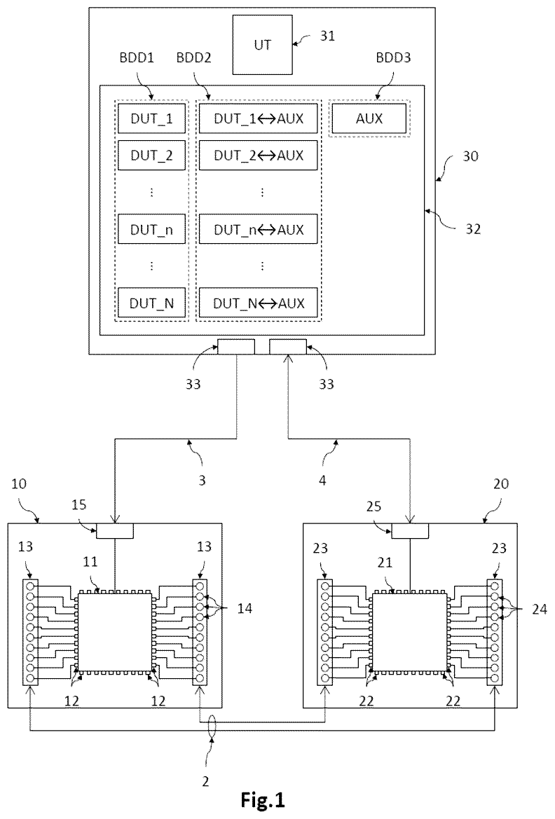

FIG. 1 schematically illustrates an electronic system 1 according to one embodiment. It is formed by a first electronic device 10, so-called under test (DUT), and a second electronic device 20, so-called auxiliary, distinct from the device under test 10, and a test computer 30.

This electronic system 1 makes it possible to test an application embedded in the device under test 10. It thus includes, more specifically: the device under test 10, which can embed the application to be tested; the auxiliary device 20, configured to communicate with the device under test 10 and with the test computer 30; and the test computer 30, configured to communicate with the auxiliary device 20 and to consult at least one database (BDD1, BDD2, BDD3). According to embodiments, it can also communicate with the device under test 10.

The database(s) allows the test computer 30 to know the second pins 22 of the microcontroller 21 of the auxiliary device 20 that are electrically connected to each first pin 12 of the microcontroller 11 of the device under test 10. The electronic system 1 may further include the database(s).

As described in detail hereinafter, the test computer 30 is configured to transmit requests to be executed to the auxiliary device 20. This includes, for example: a main request associated with an identified pin (noted 12i below) of the microcontroller 11 of the device under test 10; requests to interrogate the current state (the capacity) of the microcontroller 21 of the auxiliary device 20 to execute the main request using either of its pins 22.

By current state, it should be understood the ability of the auxiliary device 20, at the time of interrogation, to execute the main request using the interrogated pin 22 of its microcontroller 21. If the current state indicates that the main request can be executed using the interrogated pin 22, this means that pin 22 is available (not already used) and that the functionality required by the main request is supported by the interrogated pin, either by an internal device (hardware) or emulated by an algorithm (software).

The main request may relate, for example, to data to be transmitted and/or received, or to a signal to be generated or to be measured. The main request may thus consist in receiving and/or transmitting data from the device under test 10 via a communication bus, for example UART (for Universal Asynchronous Receiver Transmitter) or I2C (for Inter Integrated Circuit Bus) , or in generating or measuring a digital or analogue signal from the device under test 10, for example using an ADC (for Analogue to Digital Converter) or a DAC (for Digital to Analogue Converter). The main request is therefore associated with a pin 12 of the microcontroller 11 of the device under test 10, and with a functionality supported by the pin in question.

As indicated below, in general, each pin of a microcontroller can support one or more functionalit(y/ies), which are implemented in a hardware manner (hardware) by internal peripherals, or in an emulated manner (software) by the processor of the microcontroller. The internal peripherals can in particular implement the alternative functionalities (AF for Alternate Function) such as, for example, I2C, SPI, UART, CCP, PWM, Clock, ADC, DAC, etc.).

It is therefore a question of identifying a pin 22 of the microcontroller 21 of the auxiliary device 20 that is available (not used), that supports the functionality required by the main request, and that is connected to the pin 12i of the device under test 10 associated with the main request.

For this purpose, the test computer 30 is configured to consult the database(s) that make it possible to know the second pins 22 that are electrically connected to each first pin 12.

Thus the test computer is able to obtain data and/or generate signals associated with the device under test 10, without having to exchange directly with it. Indeed, the device under test 10 may be in the process of testing the embedded application, and it is in particular desired to obtain data regarding it, without requesting it directly by a request that would risk disturbing operation thereof, i.e. without the test computer 30 transmitting a request directly thereto without passing through the auxiliary device 20. In other words, it is not wished to alter the operation of the application to be tested, so that it can respond to requests. Furthermore, the test computer 30 may not be technically able to read most of the signals of the device under test 10 directly (i.e. without passing through the auxiliary device 20).

In one embodiment, the test computer 30 takes into account the pin mapping table (pin mapping or pin assignment) of the device under test 10, the pin mapping table of the auxiliary device 20, the table of electrical interconnection between the device under test 10 and the auxiliary device 20, and finally the current state of the auxiliary device 20 to execute the main request by either of its pins 22.

A pin mapping table corresponds to the structural configuration of the electrical connections between the pins of the microcontroller of the electronic device on the one hand, and the pins (hereinafter so-called connection ports) of its electrical connector(s) on the other hand. Thus, the connection ports give access to the pins of the microcontroller. This electrical structural configuration is generally provided by the manufacturer of the electronic device.

In an embodiment, the database(s) include: at least one mapping table for the electrical connections between the first pins 12 and the first ports 14 of the device under test 10, for example pin mapping tables 12 of various devices under test 10 likely to be used; at least one table of electrical interconnection between the first ports 14 and the second ports 24, for example tables of electrical interconnection between the devices under test 10 likely to be used and the auxiliary devices 20 likely to be used at least one mapping table for the electrical connections between the second pins 22 and the second ports 24 of the auxiliary device 20, for example pin mapping tables 22 of various auxiliary devices 20 likely to be used.

As already mentioned, these various tables can therefore be included in the same database or distributed over several databases. In the embodiment illustrated in FIG. 1, a first database BDD1 comprises the pin mapping tables of different devices under test 10 likely to be used, a second database BDD2 comprises the tables of electrical interconnection of the devices under test 10, likely to be used, with the auxiliary device 20, and a third database BDD3 comprises a pin mapping table of the auxiliary device 20. This base BDD3 can be distinct or coincident with the BDD1 base. In another embodiment, all the tables are stored in the same database.

The pin mapping tables of the various devices under test 10 that could be used, as well as the pin mapping table of the auxiliary device 20, are stored in a non-volatile memory. In addition, the tables of electrical interconnection between the various devices under test 10 that could be used on the one hand and the auxiliary device 20 on the other hand are also stored in the non-volatile memory. It could be one or more memories, for example a non-volatile memory of the test computer 30, or even a remote server, among others.

It should be noted that the non-volatile memory (of the test computer 30, of the remote server, etc.) may also comprise pin mapping tables of the different auxiliary devices 20 that could be used. In the example of FIG. 1, it is considered that only one auxiliary device model 20 is used, so that only its pin mapping table is stored in the memory of the test computer 30.

The mapping and interconnection tables allow knowing which are the second pins 22 of the microcontroller 21 of the auxiliary device 20 that are electrically connected to each first pin 12 of the microcontroller 11 of the device under test 10.

In an embodiment, the table of interconnections between the device under test 10 and the auxiliary device 20 can be modified or enhanced by the user, when additional electrical connections, for example electrical wires, have been added. These electrical wires may have been added by the user according to the test scenario to be performed and/or data to be exchanged between the device under test 10 and the auxiliary device 20.

In the embodiment of FIG. 1, the mapping and interconnection tables are stored in the non-volatile memory 32, in the same database. As mentioned previously, they could be stored in a memory of a remote server, with which the test computer 30 can communicate. They can also be stored in a memory of the same electronic device (computer, remote server, etc.) or in memories of separate electronic devices.

The device under test 10 is configured to communicate with the auxiliary device 20, and can therefore receive and/or transmit data and/or signals. It may also receive and/or transmit data from or to the test computer 30 (but this ability to communicate with the test computer 30 remains optional). It is also configured to embed an application to be tested, stored in a memory of its microcontroller.

The device under test 10 is connected to the auxiliary device 20 by one or more electrical wires 2 which can be used in particular to implement communication buses, for example of the I2C, SPI, UART type, or even to exchange signals, among other things.

The device under test 10 may be of the “master” or “controller” type, i.e. it may be at the initiative of receiving and/or transmitting data with the auxiliary device 20. The opposite is also possible. Other cases are possible where several buses are active at the same time with different controllers.

The device under test 10 is connected to the test computer 30 by a communication bus 3, separate from the communication bus 2, for example of the USB type. This communication bus 3 can be used before the test, for example to load the application and initialize the device under test 10.

The device under test 10 includes: at least one microcontroller 11; and at least one electrical connector 13 that provides access to the pins 12 of the microcontroller 11.

The microcontroller 11 comprises at least one processing unit, at least one memory, for example flash memory and RAM memory. It also includes general-purpose inputs-outputs (GPIO), interfaces for USB, I2C, SPI, USART devices. These inputs-outputs and interfaces are accessible by the pins 12 of its housing.

Thus, the microcontroller 11 comprises pins 12 such as power and ground pins, “Reset” or “Debug” pins, start-up sequence configuration pins, as well as pins that can be configured as general-purpose input-outputs (GPIO) or as an alternative function (AF).

The device under test 10 also includes at least one electrical connector 13, the connection ports 14 of which give access to the pins 12 of the microcontroller 11.

By way of example, the device under test 10 may in particular be an electronic board of the Nucleo family marketed by STMicroelectronics. The electrical connector may in particular be an ST Morpho connector.

The device under test 10 has a clean routing of the electrical connections between the pins 12 and the connection ports 14. Each pin 12 can thus be connected to one or more connection ports 14. The electrical configuration between the pins 12 and the connection ports 14 is called pin mapping table.

Thus, as example, in a Nucleo-H743ZI board, the ports 14 and 16 of the electrical connector CN8 are connected respectively to the pins PG2 and PG3 of the microcontroller, whose functions are general-purpose inputs-outputs; the ports 1, 3 and 5 of the electrical connector CN9 are connected respectively to the pins PA3, PC0 and PF3 of the microcontroller, which support the alternative function (AF) of the analog-to-digital converter (ADC). In this board, the microcontroller has 144 pins.

The device under test 10 may be powered either by the test computer 30 or by an external source, via its USB connector 15 or a connection port of an electrical connector.

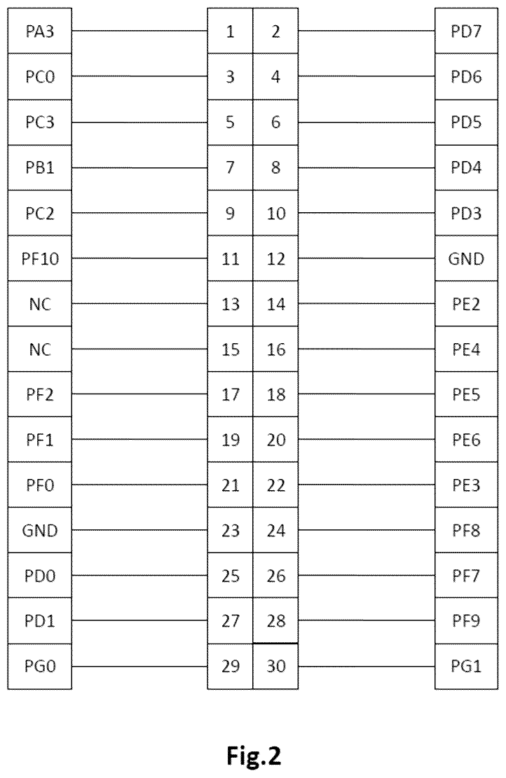

FIG. 2 schematically and partially illustrates an example of a mapping table of pins of a microcontroller with the ports of the electrical connectors of an electronic device.

In this example, the electrical connector is the CN9 connector of a NUCLEO-H743ZI electronic board. Here it has 30 connection ports, connected to certain pins of the microcontroller. Most of these pins have a general purpose input-output function, and some can be configured to have an alternative function. Thus, by way of example, the pin PA3 connected to port 1 may be configured as an ADC, UART or PWM interface, and the pin PD6 connected to port 4 may be configured as an SPI or UART interface.

It should also be noted that the same pin of a microcontroller can be connected to several connection ports of the same electrical connector or even different electrical connectors.

The auxiliary device 20 is configured to communicate with the device under test 10, and can therefore receive and/or transmit data and/or signals. It is configured to communicate with the test computer 30. It is configured to execute the interrogation requests and the main request transmitted by the test computer 30.

As indicated previously, the auxiliary device 20 is connected to the device under test 10 by one or more electrical wires 2 which can be used to implement communication buses. Furthermore, it is connected to the test computer 30 by a communication bus 4, separate from the communication bus 3, for example of the USB type.

The auxiliary device 20 includes: at least one microcontroller 21; and at least one electrical connector 23 that provides access to the pins 22 of the microcontroller 21. The microcontroller 21 and the electrical connector(s) 23 may be similar to those of the device under test 10.

The microcontroller 21 comprises at least one processing unit, at least one memory, for example flash memory and RAM memory. It also includes general-purpose inputs-outputs (GPIO), interfaces for USB, I2C, SPI, USART devices. These inputs-outputs and interfaces are accessible by the pins 22 of its housing.

The microcontroller 21 thus includes pins 22 which can be configured as general-purpose inputs-outputs (GPIO) or as an alternative function (AF).

The auxiliary device 20 also includes at least one electrical connector 23, the connection ports 24 of which provide access to the pins 22 of the microcontroller 21.

The auxiliary device 20 also has its own routing of the electrical links between the pins 22 and the connection ports 24, and therefore has its own pin mapping table.

The auxiliary device 20 may be powered either by the test computer 30 or by an external source, via its USB connector 25 or a connection port of an electrical connector.

By way of example, the auxiliary device 20 may in particular be an electronic board of the STM32 Nucleo™ family. The electrical connector may in particular be an ST Morpho connector.

The test computer 30 is configured to communicate with the auxiliary device 20. It can be configured to transmit data to the device under test 10, and optionally to receive data from it. This can be a PC type computer, a server, an onboard system, etc. It can also be called a controller or an orchestrator. It is configured to transmit to the auxiliary device 20 the interrogation requests and the main request.

It is connected to the device under test 10 by the communication bus 3, here of the USB type, via an interface 33, and to the auxiliary device 20 by the communication bus 4, here also of the USB type, via another interface 33.

It includes: at least one processing unit 31 configured to receive and/or transmit the data exchanged with the auxiliary device 20 and with the device under test 10; and at least one non-volatile memory 32.

In this embodiment, the mapping and interconnection tables are stored in the memory 32, in one or more databases BDD1, BDD2, BDD3. As noted previously, in other embodiments, they may be stored in a non-volatile memory of an electronic system different from the test computer 30, for example of a remote server to which the test computer 30 has access.

As illustrated in FIG. 1, the database BDD1 comprises all the pin mapping tables of the various devices under test 10 that could be used: {DUT_n}1,N with N≥1. When a device under test 10 is selected, it is connected to the test computer 30 and to the auxiliary device 20, and its pin mapping table is selected.

The test computer 30 can configure the auxiliary device 20, for example to indicate thereto how to respond to the requests of the device under test 10 on the communication bus 2 and to access data stored in the auxiliary device 20.

For example, the stored data are data representing information associated with the device under test 10. They can be stored in the auxiliary device 20 and can be transmitted to the test computer 10, via the communication bus 4, independently of the exchange of these data on the communication bus 2.

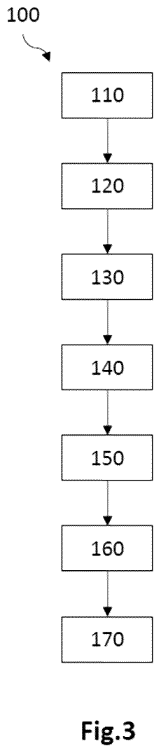

FIG. 3 illustrates steps of a method 100 according to an embodiment, of communication between the test computer 30, the auxiliary device 20, and the device under test 10.

According to one embodiment, the application embedded on the device under test 10 may be being tested. Thus various communications are carried out between the test computer 30, the auxiliary device 20, and the device under test 10.

Thus the test computer 30 may have transmitted to the auxiliary device 20 a test configuration command, for example to configure the behavior of the auxiliary device 20 in response to the requests of the device under test 10. Furthermore, the test computer 30 has transmitted to the device under test 10 the application to be executed, as well as an initialization instruction. Then, when the application is executed, data exchanges can be made between the device under test 10 and the auxiliary device 20.

In parallel with the test of the application, it is desired to transmit a main request to the auxiliary device 20, from the test computer 30. This may involve transmitting a message, for example I2C, UART, etc., transmitting a signal, for example PWM, etc.

By way of illustration, this may involve knowing the state of a peripheral of the device under test 10, for example the state of its light-emitting diode (LED). More specifically, it is desired to check that the LED of the device under test 10 is lit for a duration of 1s. For this purpose, the main request is to be transmitted to the auxiliary device 20 concerning the input-output pin PC7 of the microcontroller 11 of the device under test 10.

It is therefore a matter of identifying whether the auxiliary device 20 is capable of executing the main request using one of the pins 22 of its microcontroller 21. Therefore a pin 22 must be available that supports the functionality required by the main request (for example the presence of an ADC), and which is connected to pin 12i of the device under test 10.

During a step 110, the test computer 30 identifies the reference of the device under test 10 from a list of references stored in its memory 32. In addition, the test computer 30 can identify the reference of the auxiliary device from a list of references stored in its memory.

Of course, this operation may be absent or adapted if the test computer 30 already knows the references of the device under test and/or the auxiliary device.

The information about the type (reference) of electronic boards that are the device under test 10 and the auxiliary device 20 may be obtained automatically by the test computer 30, once connected to the boards, or may be provided by the user.

It is considered, in this example, that the device under test 10 is a NUCLEO-U575ZI electronic board and that the auxiliary device 20 is a NUCLEO-H743ZI electronic board.

It then identifies the pin mapping table associated with each electronic device 10, 20 used.

During a step 120, the test computer 30 identifies a first pin 12 of the microcontroller 11 of the device under test 10, associated with the main request to be transmitted. This first pin identified is denoted with the reference 12i. This information is provided by the user. In our example, it may be the input-output pin PC7 in the case of a NUCLEO-U575ZI electronic board, insofar as it is the pin associated with the control of the LED of the device under test 10.

During a next step 130, the test computer 30 identifies, from the mapping and interconnection tables, all the second pins 22 electrically connected to the first pin identified 12i. These second pins identified, i.e. connected to the pin 12i, are denoted with the reference 22i.

For this purpose, the test computer 30 consults the first database BDD1 (pin mapping table 12) associated with the device under test 10 used. From the first pin identified 12i, it identifies all the first connection ports 14i of the first connector(s) 13 that are connected to it.

Then it consults the second database BDD2 (interconnection table), associated with the device under test 10 and the auxiliary device 20 used, and it identifies all the second connection ports 24i connected to the first identified connection ports 14i. This step can be performed iteratively to take into account all possible connections (for example those passing through several wires).

Finally, it consults the third database BDD3 (pin mapping table 22) associated with the auxiliary device 20 used. It identifies all the second pins 22i connected to the second connection ports identified 24i.

Thus the test computer 30 has identified all of the pins 22i of the microcontroller 21 of the auxiliary device 20 connected to the identified pin 12i of the microcontroller 11 of the test device 10.

Of course, other path calculation algorithms may be used, like, for example, the A* algorithm (A* Search Algorithm) , or that one described in patent application US18/669,919 filed on May 21st, 2024.

In our example, the first database BDD1 informs that the pin PC7 (ref: 12i) of the microcontroller 11 is connected to port 12 (ref: 14i) of the connector CN12 of the device under test 10. Then, the second database BDD2 informs that port 12 is connected to port 29 (ref: 24i) of the connector CN9 of the auxiliary device 20. Finally, the third database BDD3 informs that port 29 is connected to three second pins (ref: 22i) of the microcontroller 21 of the auxiliary device 20, namely the pins PG0, PG1 and PG2.

In a next step 140, the test computer 30 transmits to the auxiliary device 20, for each second identified pin 22i, an interrogation request to know the current state (capacity) of the microcontroller 21 to execute the main request (which relates to the first identified pin 12i) using the interrogated pin 22i.

The current state of a second pin 22 may be of at least three types, to which a selection value is assigned. Thus the second pin 22 is available (not used) and the functionality required by the main request is supported by the pin 22; the selection value is noted V1. Then the second polled pin 22 may support the required functionality but is not available at the moment: the selection value is noted V3 and is less than V1. Finally, the second interrogated pin 22 may not support the required peripheral functionality: its selection value V4 is then lower than V3.

According to one embodiment, each second pin identified 22i may have the following various current states:
a “hardware support” type state, when the second pin 22i is available and supports the functionality required by the main request in a hardware manner by an internal peripheral. The selection value V1 can be+2;
a state of the “software support” type, when the second pin 22i is available and supports the required functionality, which is implemented in a non-hardware but emulated manner. A selection value V2 is less than V1, and can here be +1;
a “busy” type state, when the second pin 22i supports the required functionality, but is not able to process the desired main request for the time being in a hardware or emulated manner. A selection value V3 is less than V2, and may here be −1;
a “no support” type state, when the second pin cannot process the main request in general, because it would not support the required functionality. A selection value V4 is less than V3, and may here be −2;

It should be noted that, if no pin 22i is found, the process stops, informs the user thereof, and no main request is transmitted to the auxiliary device 20.

In our example, the test computer 30 sends an interrogation request to the auxiliary device 20 regarding the second pin PG0: “st cgpd PG0”, an interrogation request regarding the second pin PG1: “st cgpd PG1”, and an interrogation request regarding the second pin PG2: “st cgpd PG2”. Of course, the query syntax is given here as an example only, other syntaxes are possible.

During a following step 150, the test computer 30 receives a response from the auxiliary device 20 on the current state of each second pin identified 22i, and assigns a selection value according to the response.

Thus, in our example, the test computer 30 receives the response of the second pin PG0, which is of the “hardware support” type, and assigns the selection value V1=+2: V_PG0=V1=+2. It receives the response from the second pin PG1, which is of the “busy” type, and assigns the selection value V_PG1=V3=−1. It receives the response from the second pin PG2, which is of the “software support” type and assigns the selection value V_PG2=V2=+1.

During a following step 160, the test computer 30 selects the second pin identified 22i as being that whose selection value is greater than a selection threshold and is the highest. This pin is marked with the reference 22is.

Indeed, it is understood that, if the various pins identified 22i are not available or the required functionality of which is not supported, they have a selection value lower than the selection threshold, and the test computer 30 then does not transmit the main request.

In our example, the second selected pin 22is is the pin PG0 insofar as its selection value V_PG0 is not only positive (selection threshold set here to 0) and is the highest.

Finally, during a subsequent step 170, the test computer 30 transmits to the auxiliary device 20 the main request, which mentions the second selected pin 22is, the latter being electrically connected to the first identified pin 12i. This main request is then executed by the auxiliary device 20, then, if necessary, transmits the response to the test computer 30.

In our example where the second selected pin 22is is the pin PG0, the test computer 30 transmits the main request “cgpd PG0 1 1000” to the auxiliary device 20. Insofar as its pin PG0 is connected to the pin PC7 of the device under test 10, the very one that is connected to the LED, the auxiliary device 20 executes the main request and then responds to the test computer 30 by giving the state of the LED, i.e. 1 if it is lit for a duration of 1000 ms, or 0 otherwise.

Thus it can be seen that, by this communication method, the test computer 30 is able to transmit a request to the auxiliary device to obtain data representing the device under test, even though the latter is in the process of testing the embedded application. Thus the test computer can obtain this data without interacting directly with the device under test 10. In addition, the auxiliary device 20 may be a generic device that is unaware of the nature or arrangement of the device under test 10, or its connections thereto.

For this purpose, the method takes into account the structural configuration of the electrical connections of each electronic device 10, 20, the configuration of interconnection between these two electronic devices 10, 20, and the current state of the auxiliary device 20.

Thus one or more databases are used, which make it possible to know which are the second pins 22 that are electrically connected to each first pin 12. They include the pin mapping tables of the devices 10, 20, as well as the table of interconnection between the devices 10, 20. This or these databases are static, and correspond to the electrical structural configuration of the electronic devices as specified by the manufacturer. However, the interconnection table can be adapted by the user according to the tests to be performed.

Furthermore, the method also takes into account the current state of the auxiliary device 20 to process or not the main request.

The communication method can be termed hybrid, since it takes into account the (static) tables of the electrical connections as well as the current (dynamic) state of the auxiliary device 20.

Embodiments have just been described. Different variants and modifications will appear to those skilled in the art.

What is claimed is:

1. An electronic system, including:
a first electronic device comprising
a first microcontroller that comprises first pins, and
at least one first electrical connector comprising first ports, each first port being electrically connected to at least one of the first pins;
a second electronic device separate from the first electronic device and configured to communicate with at least the first electronic device and to receive and execute requests from a test computer, the second electronic device comprising
a second microcontroller comprising second pins, and
at least one second electrical connector comprising second ports, each second port being electrically connected to at least one of the second pins, the second electrical connector being electrically connected to the first electrical connector to communicate with the first electronic device;
the test computer configured to communicate with at least the second electronic device and to consult at least one database to determine which of the second pins are electrically connected to each of the first pins, the test computer comprising a processor and a memory storing a program and coupled to the processor, the processor configured to execute the program comprising instructions that when executed enable the processor to:
identify, from the at least one database, all the second pins electrically connected to a first identified pin associated with a main request to be transmitted;
transmit to the second electronic device, and for each of the second pins electrically connected to the first identified pin, a request to interrogate a current state of the second microcontroller to execute the main request using the second identified pin;
receive from the second electronic device a response for each of the second pins electrically connected to the first identified pin, each response indicating the current state of the second microcontroller for each of the second pins identified;
select a second selected pin from the second pins identified, according to the responses received; and
transmit to the second electronic device said main request that specifies the second selected pin, the second selected pin being electrically connected to the first identified pin.

2. The electronic system according to claim 1, wherein the identification step is implemented by the test computer using:
at least one mapping table of the electrical connections between the first pins and the first ports of the first electronic device;
at least one table of electrical interconnection between the first ports and the second ports;
at least one mapping table of the electrical connections between the second pins and the second ports of the second electronic device;
said tables being stored in said at least one database.

3. The electronic system of claim 1, wherein the program further comprises instructions that enable the processor to identify a first pin associated with the main request to be transmitted.

4. The electronic system according to claim 1, wherein the program further comprises instructions that enable the processor to:
assign a selection value to each second identified pin according to its response; and
when selecting, select the second pin with the highest value.

5. The electronic system according to claim 4, wherein, upon selection, the second pin selected has the highest value and higher than a selection threshold.

6. The electronic system according to claim 4, wherein the program further comprises instructions that enable the processor to assign:
a first value when the second pin identified and interrogated is available and it supports a functionality required by the main request in a hardware manner;
a second value, lower than the first value, when the second pin identified and interrogated is available and it supports a functionality required by the main request in an emulated manner;
a third value, lower than the second value, when the second pin identified and interrogated supports said required functionality but is not available; and
a fourth value, lower than the third value, when the second pin identified and interrogated does not support said required functionality.

7. The electronic system of claim 1, wherein:
said at least one database comprises pin mapping tables of different first electronic devices; and
the program further comprises instructions that enable the processor to identify the first electronic device connected to the second electronic device, and to identify, in the first database, the associated pin matching table.

8. The electronic system according to claim 1, wherein the first microcontroller comprises a memory in which an embedded application to be tested is stored.

9. The electronic system according to claim 1, wherein said at least one database is stored in a non-volatile memory of the test computer, or of a remote server.

10. A method for communicating between a first electronic device, a second electronic device, and a test computer, wherein:
the first electronic device comprises a first microcontroller having first pins, and at least one first electrical connector having first ports, each first port being electrically connected to at least one of the first pins;
the second electronic device is separate from the first electronic device and is configured to communicate with at least the first electronic device and to receive and execute requests from the test computer, the second electronic device comprising a second microcontroller having second pins, and at least one second electrical connector having second ports, each second port being electrically connected to at least one of the second pins, the second electrical connector being electrically connected to the first electrical connector to communicate with the first electronic device; and
the test computer is configured to communicate with at least the second electronic device and to consult at least one database to determine which of the second pins are electrically connected to each of the first pins,
the method comprising:
identifying, from said at least one database, the second pins electrically connected to a first identified pin associated with a main request to be transmitted;
transmitting to the second electronic device, for each of the second pins electrically connected to the first identified pin, a request to interrogate a current state of the second microcontroller to execute the main request using said second pin;
receiving from the second electronic device a response for each of the second pins electrically connected to the first identified pin, each response indicating the current state of the second microcontroller;
selecting a second selected pin from the second pins electrically connected to the first identified pin according to the responses received; and
transmitting to the second electronic device said main request that specifies the second selected pin, the second selected pin being electrically connected to the first identified pin.

11. The method according to claim 10, further comprising before identifying the second pins electrically connected to the first identified pin: identifying, by the processor, the first pin associated with the main request to be transmitted.

12. The method according to claim 10, further comprising:
assigning, by the processor, a selection value to each of the second pins electrically connected to the first identified pin according to its response; and
during the selection of the second selected pin, selecting, by the processor, the second pin that has the highest value.

13. The method according to claim 10, wherein the first electronic device comprises an embedded application; and wherein, from transmitting the interrogation requests to transmitting the main request, the first electronic device tests the embedded application.

14. The method according to claim 10, further comprising, after transmitting the main request, executing the main request by the second electronic device using the second selected pin.

15. An electronic system for testing an embedded application, comprising:
a device under test comprising a first microcontroller having first pins;
an auxiliary device separate from the device under test and electrically connected thereto, the auxiliary device comprising a second microcontroller having second pins, wherein one or more of the second pins are electrically connected to one or more of the first pins; and
a test computer configured to:
consult at least one database to identify second pins electrically connected to a target first pin associated with a request to be executed;
transmit to the auxiliary device, for each of the identified second pins, an interrogation request to determine a current state of the second microcontroller for executing the request using said second pin;
receive from the auxiliary device responses indicating the current state for each of the identified second pins;
select one of the identified second pins based on the responses received; and
transmit the request to the auxiliary device specifying the selected second pin for execution.

16. The electronic system of claim 15, wherein the current state indicates at least one of: whether the second pin is available, and whether the second pin supports a functionality required by the request.

17. The electronic system of claim 16, wherein the test computer is configured to select the second pin based on whether the second pin supports the required functionality in a hardware manner or in an emulated manner.

18. The electronic system of claim 15, wherein the at least one database comprises:
at least one mapping table for electrical connections between the first pins and first connector ports of the device under test;
at least one interconnection table for electrical connections between the first connector ports and second connector ports; and
at least one mapping table for electrical connections between the second connector ports and the second pins of the auxiliary device.

19. The electronic system of claim 15, wherein the test computer is configured to obtain data from the device under test via the auxiliary device without transmitting a request directly to the device under test.

20. The electronic system of claim 15, wherein the device under test is configured to execute the embedded application concurrently with the auxiliary device executing the request.
